(19) United States
(12) Patent Application Publication
(10) Pub. No.: US 2020/0350169 A1
(43) Pub. Date: Nov. 5, 2020

(54) WAFER BONDING METHOD

(71) Applicant: HUAIAN IMAGING DEVICE MANUFACTURER CORPORATION, Huaian (CN)

(72) Inventors: Xian Zhou, Huaian (CN); Yang Chao, Huaian (CN); Xiaolu Huang, Huaian (CN)

(73) Assignee: HUAIAN IMAGING DEVICE MANUFACTURER CORPORATION, Huaian (CN)

(21) Appl. No.: 16/562,810

(22) Filed: Sep. 6, 2019

(30) Foreign Application Priority Data
Apr. 30, 2019 (CN) 201910358104.2

(51) Int. Cl. H01L 21/18; H01L 21/02

(52) U.S. Cl. CPC H01L 21/187; H01L 21/02664; H01L 21/02021; H01L 21/02013; H01L 21/02601

(57) ABSTRACT

A wafer bonding method comprises providing a first wafer and a second wafer, the first wafer having a first metal layer and a first insulating layer at a first surface thereof, the second wafer having a second metal layer and a second insulating layer at a first surface thereof, the first metal layer and the second metal layer comprising a same metal material; pretreating one or both of the first wafer and the second wafer, so that whiskers of the metal material are formed at a surface or surfaces of the one or both of the first metal layer and the second metal layer; and bonding the first metal layer and the second metal layer in a manner that the first metal layer and the second metal layer face each other, to bond the first wafer and the second wafer.

### CROSS-REFERENCE TO THE RELATED APPICATIONS

The present application claims the benefit and priority to Chinese application No. 201910358104.2, filed on Apr. 30, 2019, which is incorporated herein by reference in its entirety.

### TECHNICAL FIELD

The present disclosure relates to a wafer bonding method.

### BACKGROUND

In a conventional technique utilizing metal-metal bonding to bond wafers, after chemical mechanical polishing (CMP) to planarize a wafer surface a dishing may appear at a metal surface, especially for copper (Cu). If a pressure is insufficient or the dishing is too large during later bonding procedure, it may result in a void at the contact interface after the wafers are bonded, which may adversely affect the bonding strength.

Therefore, there is a need for an improved wafer bonding technique.

### SUMMARY

In view of the above described problem(s) at least, the present application is proposed to provide an improved wafer bonding technique.

According to an aspect of the present disclosure, there is provided a wafer bonding method comprising: providing a first wafer and a second wafer, the first wafer having a first metal layer and a first insulating layer at a first surface thereof, the second wafer having a second metal layer and a second insulating layer at a first surface thereof, the first metal layer and the second metal layer comprising a same metal material; pretreating one or both of the first wafer and the second wafer, so that whiskers of the metal material are formed at a surface or surfaces of the one or both of the first metal layer and the second metal layer; and bonding the first metal layer and the second metal layer in a manner that the first metal layer and the second metal layer face each other, to bond the first wafer and the second wafer.

In some embodiments, the metal material comprises copper. The pretreatment may comprise: performing a sulphidation treatment on the one or both of the first metal layer and the second metal layer with a sulfur-containing liquid to form a sulfide of copper at the surfaces or surfaces of the one or both of the first metal layer and the second metal layer; and performing a reduction treatment on the sulfide of copper in a reducing atmosphere to form copper whiskers at the surface or surfaces of the one or both of the first metal layer and the second metal layer.

In some embodiments, the method further comprises: performing an annealing treatment on the first wafer and the second wafer which are bonded.

In some embodiments, an edge portion of the first metal layer is substantially flush with the first insulating layer at the first surface of the first wafer; and an edge portion of the second metal layer is substantially flush with the second insulating layer at the first surface of the second wafer.

In some embodiments, the providing a first wafer and a second wafer comprises: performing a planarization treatment on the first wafer so that an edge portion of the first metal layer is substantially flush with the first insulating layer at the first surface of the first wafer; and performing a planarization treatment on the second wafer so that an edge portion of the second metal layer is substantially flush with the second insulating layer at the first surface of the second wafer. In some embodiments, the planarization treatment comprises chemical mechanical polishing (CMP).

In some embodiments, the sulfur-containing liquid comprises thiourea or thiourea solution, the sulphidation treatment is performed at a temperature ranging from 90° C. to 400° C. and for a period ranging from several minutes to several hours.

In some embodiments, the reducing atmosphere comprises hydrogen, the reduction treatment is performed at a temperature ranging from 150° C. to 400° C. and for a period ranging from several minutes to several hours.

In some embodiments, bonding the first metal layer and the second metal layer in a manner that that the first metal layer and the second metal layer face each other to bond the first wafer and the second wafer comprises: bonding the first metal layer and the second metal layer with thermo-compression bonding, to bond the first wafer and the second wafer.

In some embodiments, the annealing treatment is performed at a temperature ranging from 300° C. to 400° C. and for a period ranging from several minutes to several hours.

In some embodiments, after the pretreating and before bonding the first metal layer and the second metal layer, the method further comprises: forming nanoparticles of the metal material on the surface or surfaces of the one or both of the first metal layer and the second metal layer, on which the whiskers of the metal material are formed, with electrochemical deposition.

In some embodiments, the method further comprises, after the pretreating and before bonding the first metal layer and the second metal layer, performing a shaping treatment on the whiskers.

In some embodiments, after the pretreating and before bonding the first metal layer and the second metal layer, the method further comprises: performing a shaping treatment on the whiskers; and forming, after the shaping treatment, whiskers of the metal material again on the surface or surfaces of the one or both of the first metal layer and the second metal layer on which the whiskers of the metal material are formed.

According to another aspect of the present disclosure, there is provided a wafer bonding method comprising: providing a first wafer and a second wafer, the first wafer having a first metal layer and a first insulating layer at a first surface thereof, the second wafer having a second metal layer and a second insulating layer at a first surface thereof, and the first metal layer and the second metal layer comprising a same metal material; performing a pretreatment on one or both of the first wafer and the second wafer to form a compound of the metal material at a surface or surfaces of the one or both of the first metal layer and the second metal layer; bonding the first wafer and the second wafer in a manner that the first metal layer and the second metal layer face each other; and performing a treatment on the first wafer and the second wafer which are bonded, to convert the compound of the metal material into whiskers of the metal material.

In some embodiments, the metal material comprises copper, and the compound of the metal material comprises sulfide of copper. The pretreatment may comprise: performing a sulphidation treatment on the one or both of the first metal layer and the second metal layer with a sulfur-containing liquid to form sulfide of copper at the surface or surfaces of the one or both of the first metal layer and the second metal layer.

In some embodiments, the metal material comprises copper, and the compound of the metal material comprises sulfide of copper. In some embodiments, performing the treatment on the first wafer and the second wafer bonded may comprise: performing an annealing treatment on the sulfide of copper in a reducing atmosphere to form copper whiskers at the surface or surfaces of the one or both of the first metal layer and the second metal layer.

In some embodiments, at the first surface of the first wafer, an edge portion of the first metal layer is substantially flush with the first insulating layer; and at the first surface of the second wafer, an edge portion of the second metal layer is substantially flush with the second insulating layer.

In some embodiments, providing the first wafer and the second wafer comprises: performing a planarization treatment on the first wafer, so that an edge portion of the first metal layer is substantially flush with the first insulating layer at the first surface of the first wafer; and performing a planarization treatment on the second wafer, so that an edge portion of the second metal layer is substantially flush with the second insulating layer at the first surface of the second wafer. In some embodiments, the planarization treatment comprises chemical-mechanical polishing.

In some embodiments, the sulfur-containing liquid comprises thiourea or thiourea solution, and the sulphidation treatment is performed at a temperature ranging from 90° C. to 400° C. and for a period ranging from several minutes to several hours.

In some embodiments, the annealing treatment is performed at a temperature ranging from 300° C. to 400° C. and for a period ranging from several minutes to several hours.

Others features and advantages of the present disclosure can become apparent from the following detailed description of exemplary embodiments of the present disclosure with reference to the accompanying drawings.

### BRIEF DESCRIPTION OF THE DRAWINGS

The accompanying drawings, which constitute a part of the specification, illustrate embodiments of the present disclosure and, together with the description, serve to explain the principles of the present disclosure.

The present disclosure can be understood more clearly from the following detailed description with reference of the accompanying drawings in which:

FIGS. 1A and 1B are schematic cross-sectional views which illustrate a wafer bonding technique;

FIG. 2 is a flow chart of a wafer bonding method according to an embodiment of the present disclosure;

FIGS. 3A-3D are schematic cross-sectional views which illustrate wafers bonded according to a wafer bonding method of an embodiment of the present disclosure, in the steps of the method, respectively;

FIG. 4 is a flow chart of a wafer bonding method according to another embodiment of the present disclosure; and

FIGS. 5A-5E are schematic cross-sectional views which illustrate wafers bonded according to a wafer bonding method according to another embodiment of the present disclosure, in the steps of the method, respectively.

Note that, in the following illustrative implementations, in some cases the same portions or portions having a same function are denoted by a same reference numeral in different drawings, and description of such portions will not be repeated. In the present specification, similar reference numerals and letters are used to refer to similar items, therefore once an item is defined in one figure, it need not be further discussed for following figures.

In order to facilitate understanding, positions, sizes, ranges, and the like of respective structures illustrated or described in the drawings and the like are not intended to represent the actual positions, sizes, ranges, and the like in some cases. Therefore, the disclosed inventions shall not be limited to the positions, the sizes, the ranges, and the like as disclosed in the drawings and the like.

### DETAILED DESCRIPTION OF ILLUSTATIVE EMBODIMENTS

Various exemplary embodiments of the present disclosure will now be described in detail with reference to the accompanying drawings. It should be noted that the relative arrangement of components or steps, the numerical expressions, and numerical values set forth in these embodiments are not intended to limit the scope of the present disclosure unless it is specifically stated otherwise. In addition, techniques, methods, and apparatus as known by those skilled in the art may be not discussed in detail, but those techniques, methods, and apparatus should be regarded as a part of the specification where appropriate.

The terms such as “front”, “back”, “top”, “bottom”, “over”, “under” and the like, as used in the specification and claims, if any, are used for descriptive purpose and not necessarily for describing permanent relative positions. It should be understood that such terms as used can be interchangeable under appropriate circumstances, so that the embodiments of the present disclosure described herein are, for example, capable of operating in other orientations than those illustrated or described herein.

Any implementation/embodiment exemplarily described herein shall not be regarded as preferred or advantageous over other implementation/embodiment. Furthermore, the present disclosure shall not be limited by any of the stated or implied theory presented in above technical field, background, summary or detailed description.

In the present specification, the term “semiconductor device” refers to any device that can operate partially or entirely by utilizing a semiconductor characteristic of a semiconductor element. Therefore, semiconductor device may comprise electro-optics devices, photoelectrical devices, semiconductor circuits, electronic devices.

In addition, certain terminology may also be used in the following description for purpose of reference only, and thus are not intended to be limiting. For example, the terms “first”, “second”, and other such numerical terms leading a structure or element do not imply any sequence or order unless expressly indicated otherwise by the context.

Further, it should be understood that, the terms “comprise” or “include” and its variants, as used herein, specify the presence of indicated features, integers, steps, operations, units and/or components, but do not preclude the presence or addition of one or more other features, integers, steps, operations, units and/or components, and/or any combinations thereof.

In the present disclosure, the term “provide” or its variants are intended in a broad sense to embrace all the ways of obtaining an object, therefore “providing an object” includes but is not limited to “purchasing”, “preparing/manufacturing”, “disposing/arranging”, “installing/assembling”, and/or “ordering” the object, or the like.

The following description of the exemplary embodiments is illustrative only and is not intended to limit the present disclosure or any application and usage thereof.

In a technique utilizing the metal-metal bonding to bond wafers, after a planarization on a wafer surface with chemical mechanical polishing (CMP), a dishing may appear at the metal surface, especially for copper (Cu).

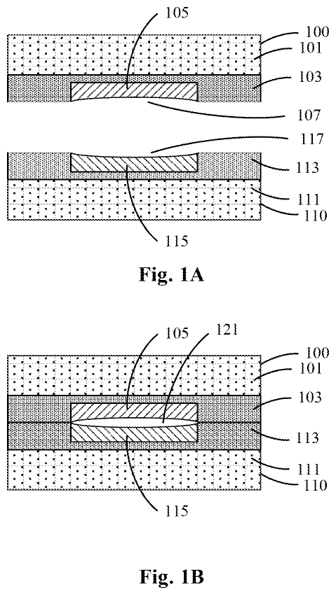

FIGS. 1A and 1B are schematic cross-sectional views of a wafer bonding technique. As shown in FIG. 1A, a wafer 100 has a first insulating layer 103 and a first metal layer 105 at a first surface . A second wafer 110 has a second insulating layer 113 and a second metal layer 115 at a first surface. After a planarization treatment (e.g., chemical mechanical polishing (CMP)) on the wafers 100 and 110so that the insulating layers are substantially flush with the respective metal layers, recesses (i.e., the dishing) 107 and 117 are formed at the surfaces of the metal layers 105 and 115. Here, it should be understood that for clear illustration clearly, dimensions of the components in the drawings are not necessarily to be draw in scale, and the dimensions of some components may be exaggerated relative to other components.

If a pressure is insufficient in a later bonding procedure or the recess is too large, it may result in a void 121 at a contact interface after the wafer is bonded, as shown in FIG. 1B. Thereby, the wafer bonding strength may be adversely affected, and yield and reliability may be reduced.

In view of this, the inventors of the present application propose the inventions disclosed herein to provide a novel wafer bonding technique to alleviate or eliminate one or more problems described above.

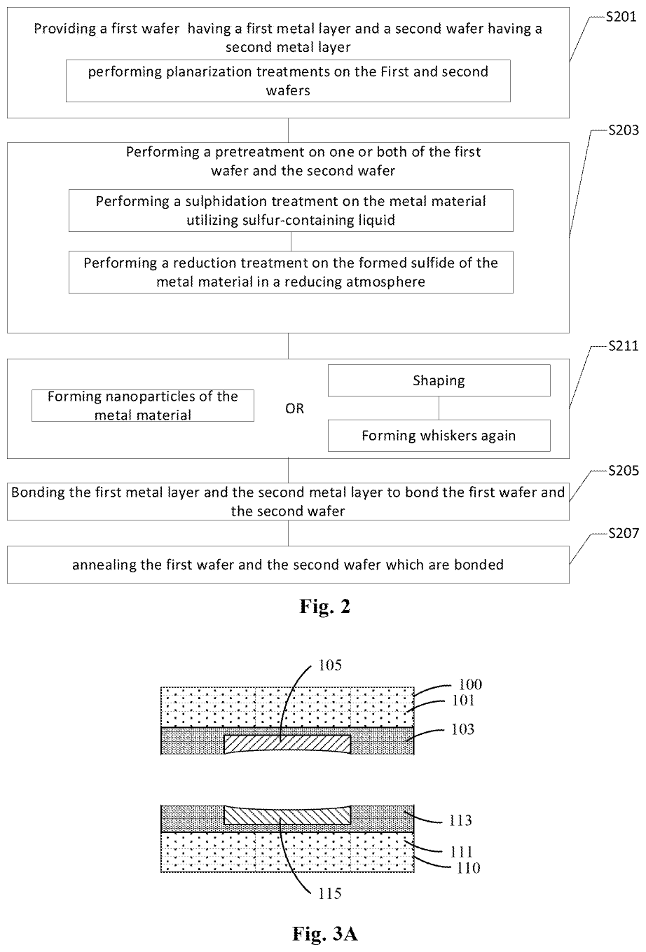

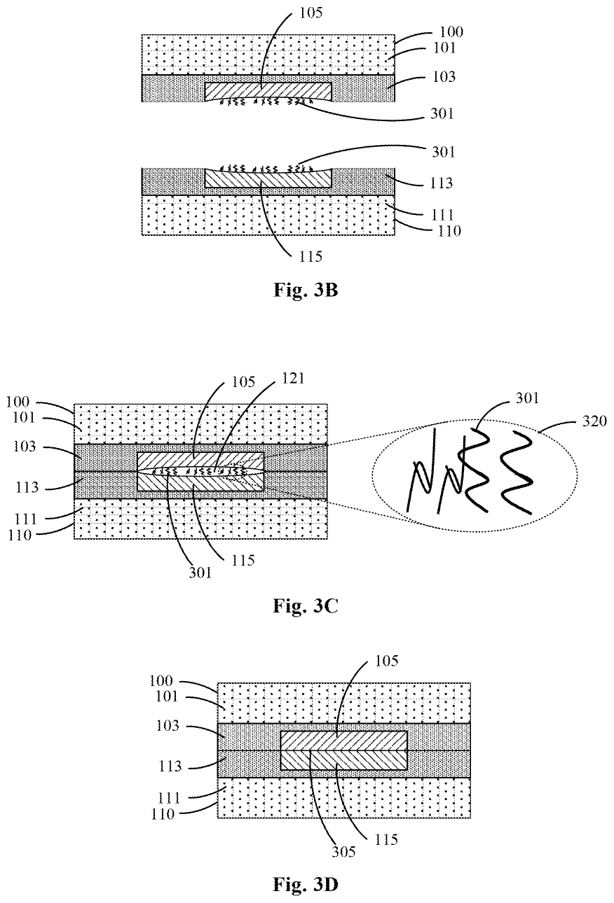

FIG. 2 is a flow chart of a wafer bonding method according to an embodiment of the present disclosure. FIGS. 3A-3D are schematic cross-sectional views which illustrate wafers, in respective processing steps, bonded according to a wafer bonding method according to the embodiment of the present disclosure. Descriptions will be given below with reference to FIG. 2 and FIGS. 3A-3D.

According to the embodiment of the present disclosure, a wafer bonding method is provided. As shown in FIG. 2, the wafer bonding method may include the following steps.

In step S201, a first wafer and a second wafer are provided. As shown in FIG. 3A, the first wafer 100 has a first insulating layer 103 and a first metal layer 105 at a first surface. The second wafer 110 has a second insulating layer 113 and a second metal layer 115 at a first surface. The first metal layer 105 and the second metal layer 115 may comprise a same metal material, such as copper (Cu).

The first wafer 100 may also have a substrate 101. Similarly, the second wafer 110 may also have a substrate 111. Those skilled in the art will readily understand that the substrates 101 and 111 each may comprise, but is not limited to, one or more of the followings: a semiconductor layer, an insulating layer, a conductor layer, and the like.

In some implementations, at the first surface of the first wafer 100, an edge portion of the first metal layer 105 is substantially flush with the first insulating layer. At the first surface of the second wafer 110, an edge portion of the second metal layer 115 is substantially flush with the second insulating layer.

In some implementations, providing the first wafer and the second wafer may comprise: performing planarization treatments on the wafers. For example, a planarization treatment is performed on the first wafer 100, so that the edge portion of the first metal layer 105 is substantially flush with the first insulating layer 103 at the first surface of the first wafer 100. a planarization treatment is performed on the second wafer 110, so that the edge portion of the second metal layer 115 is substantially flush with the second insulating layer 113 at the first surface of the second wafer 110. Here, those skilled in the art will readily understand that although the purpose of the planarization treatment is to make the metal layer be substantially flush with the corresponding insulating layer 113, as described previously the planarization treatment (such as, CMP) may result in undesired recesses (dishing) at the surfaces of the first metal layer 105 and the second metal layer 115. In addition, it should also be understood that in the procedure of forming the substantially flush metal layer, there may be an undesired recess introduced unintentionally at the surface of the metal layer for various reasons, thereby the bonding quality may be adversely affected.

In FIG. 3A, the first metal layer 105 and the second metal layer 115 each are shown to have a recess. However, it should be understood that the present disclosure is not limited thereto. For example, one or both of the first metal layer 105 and the second metal layer 115 may also have no recess. For such a case, the teaching of the embodiments of the present disclosure may still be applied similarly or adaptively.

Next, in step S203, a pretreatment is performed on one or both of the first wafer and the second wafer. As shown in FIG. 3B, a pretreatment is performed on one or both of the first wafer 100 and the second wafer 110, so that whiskers of the metal material are formed at the surface or surfaces of the corresponding one or both of the first metal layer 105 and the second metal layer 115.

In some embodiments, the metal material may comprise copper (Cu). For example, the first metal layer 105 and the second metal layer 115 may both be formed of copper. But it should be understood that the present application is not limited thereto.

In some embodiments, the pretreatment may comprise the following steps.

First, a sulphidation treatment is performed on the metal material utilizing sulfur-containing liquid. Specifically, the sulphidation treatment may be performed on the metal material of one or both of the first metal layer 105 and the second metal layer 115 utilizing the sulfur-containing liquid to form sulfide of the metal material at the surface or surfaces of the one or both of the first metal layer 105 and the second metal layer 115.

In some specific implementations, the sulfur-containing liquid comprises thiourea (CH₄N₂S) or thiourea solution (i.e., solution which contains thiourea). The sulphidation treatment may be performed at a temperature ranging from 90° C. to 400° C. and for a period ranging from several minutes to several hours. For example, the sulphidation treatment may be performed to one or both of the first metal layer 105 and the second metal layer 115 at 90° C. for several minutes to 1 hour (e.g., 30 minutes) utilizing the thiourea solution. For another example, the sulphidation treatment may be performed on one or both of the first metal layer 105 and the second metal layer 115 at a temperature of 150° C.-350° C. for several minutes to 30 minutes utilizing the thiourea solution by a reactor.

Thereafter, a reduction treatment is performed on the formed sulfide of the metal material in a reducing atmosphere. Thereby, copper whiskers 301 may be formed at the surface or surfaces of the one or both of the first metal layer 105 and the second metal layer 115, as shown in FIG. 3B.

The reducing atmosphere may comprise, but is not limited to, hydrogen. The reducing atmosphere may comprise mixed gas of hydrogen and inert gas. In some implementations, the reduction treatment is performed at a temperature ranging from 150° C. to 400° C. and for a period ranging from several minutes to several hours. Preferably, the reduction treatment may be performed in a hydrogen atmosphere at a temperature of 350° C. or below for several minutes to 1 hour (e.g., 30 minutes).

It should be understood that the length of the whiskers to be formed (and, corresponding process conditions, etc.) may be set according to the size of the recess in the metal layer. For example, in the case that a planarization is performed on the metal layer of the wafer with CMP, it is preferred to grow whiskers of a length of about ten nanometers to several hundreds of nanometers.

Thereafter, in step 205, the first metal layer and the second metal layer are bonded to bond the first wafer and the second wafer. In a specific implementation, as shown in FIG. 3C, the first metal layer 105 and the second metal layer 115 may be bonded in a manner that the first metal layer 105 and the second metal layer 115 face each other to bond the first wafer 100 and the second wafer 110. An enlarged view 320 of a portion of the whiskers 301 is also shown in FIG. 3C. The whiskers grown from the surface of the metal layer may form hook and stick structures to be joined to each other, thereby the bonding strength of the copper surfaces can be enhanced, and the void can be reduced.

In addition, according to the embodiments of the present disclosure, the whiskers may be selectively grown at the surface of the metal (e.g. copper), while whiskers cannot be grown at the surface of a material other than the metal (e.g. non-copper), for example, at a surface of the insulating layer (e.g., TEOS/SiN). Therefore, it is possible to not affect the bonding of other interface (if needed) and its bonding strength.

In some embodiments, the first metal layer 105 and the second metal layer 115 may be bonded by compression or thermo-compression bonding to bond the first wafer 100 and the second wafer 110.

In some embodiments, the method may further comprise: in step S207, annealing the first wafer and the second wafer which are bonded. As shown in FIG. 3D, an annealing treatment is performed on the first wafer 100 and second wafer 110 which are bonded, to further fill (or eliminate) the void, thereby the interface 305 can be further improved and the bonding strength can be enhanced.

In some embodiments, the annealing treatment may be performed at a temperature ranging from 300° C. to 400° C. and for a period ranging from several minutes to several hours. For example, the annealing treatment may be performed at a temperature of 350° C. for a period of several minutes to 1 hour (e.g., 30 minutes).

According to some embodiments of the present disclosure, the method may further comprise additional step(s). As shown in FIG. 2, in some embodiments, the method may further comprise: in step S211, after forming the whiskers (in step S203), nanoparticles of the metal material (e.g., copper) are formed, utilizing an electrochemical deposition, at the surface or surfaces of the corresponding one or both of the first metal layer 105 and the second metal layer 115 on which the whiskers of the metal material (e.g., copper) are formed. Thereafter, in step S205, the first metal layer and the second metal layer are bonded, to bond the first wafer and the second wafer.

In some implementations, copper nanoparticles may be formed utilizing copper-containing solution (e.g., copper sulfate solution, etc.) by electrochemical deposition method.

As such, nanoparticles of the metal material can be formed on the surface on which the whiskers of the metal material (e.g., copper) are formed and on the whiskers, thereby the morphologies of the surface and the whiskers formed thereon can be further improved. Thus, the recess on the surface of the metal layer may be filled more sufficiently, thereby the void may be further reduced and the bonding strength may be enhanced.

According to still other alternative embodiments of the present disclosure, the method may further comprise: a step of shaping the whiskers after forming the whiskers (step S203). In an exemplary implementation, diluted etchant (for example, but not limited to, diluted nitric acid, etc.) may be utilized to dissolve a portion of the surface of the metal material (including the whiskers). Thereby, morphology structures of the surface and the whiskers formed thereon can be further improved, and the properties of the whiskers can be further improved, for example, the distribution of the whiskers may be changed (e.g., the uniformity of the distribution thereof may be changed), the sizes of the whiskers may be reduced (e.g., lengths and lateral sizes, etc.). Thereafter, the step of growing whiskers may be performed again; since it can be similar to the step S203, thus will not be described here in detail again. The step of shaping and the step of forming whiskers again may be performed once or more times. As such, the recess on the surface of the metal layer may be filled more sufficiently, thereby the void may be further reduced, the bonding strength may be enhanced.

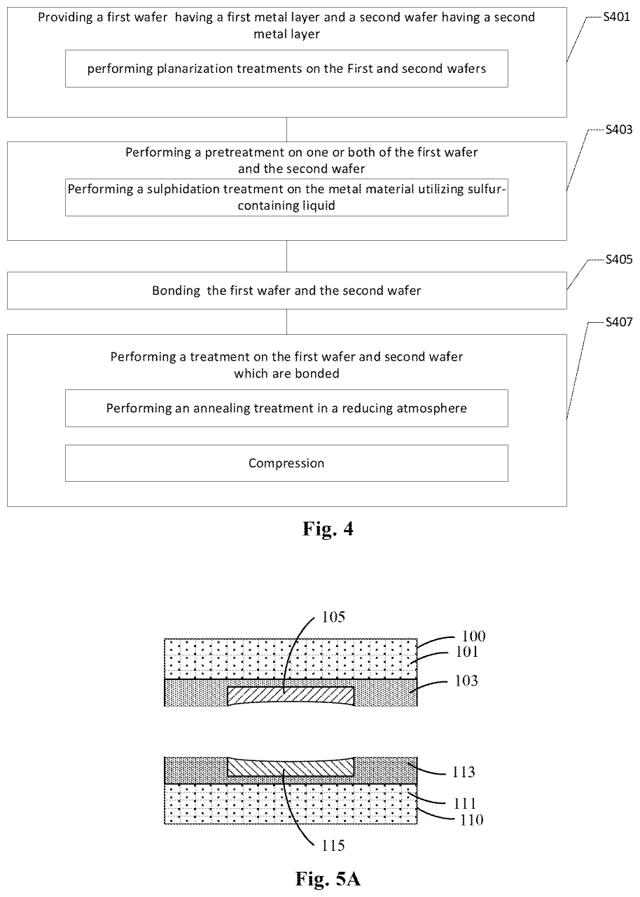

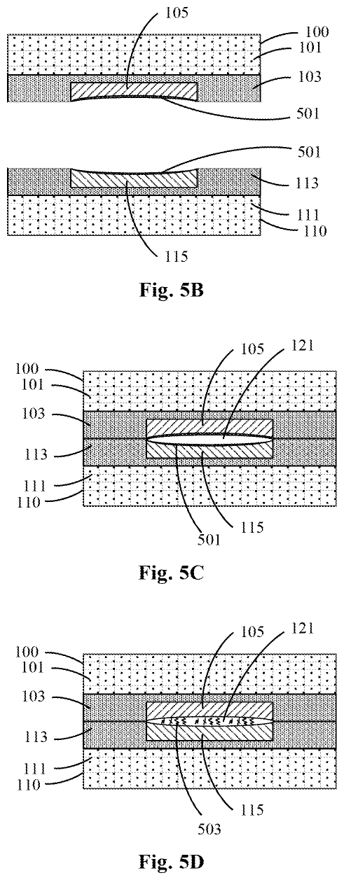

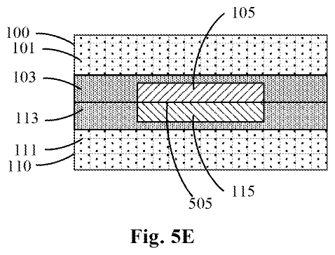

FIG. 4 is a flow chart of a wafer bonding method according to another embodiment of the present disclosure. FIGS. 5A-5E are schematic cross-sectional views which illustrate wafers bonded in respective processing steps of the wafer bonding method according to another embodiment of the present disclosure. Descriptions will be given below with reference to FIG. 4 and FIGS. 5A-5E.

According to some other embodiments of the present disclosure, a wafer bonding method is also provided. As shown in FIG. 4, the wafer bonding method may comprise the following steps.

In step S401, a first wafer and a second wafer are provided, the first wafer has a first metal layer at a first surface, and the second wafer has a second metal layer at a first surface. In some embodiments, as shown in FIG. 5A, a first wafer 100 and a second wafer 110 are provided. The first wafer 100 has a first metal layer 105 and a first insulating layer 103 at a first surface, and the second wafer 110 has a second metal layer 115 and a second insulating layer 113 at a first surface. The first metal layer 105 and the second metal layer 115 may be formed of a same metal material (e.g., copper (Cu)).

The first wafer 100 may also have a substrate 101. Similarly, the second wafer 110 may also have a substrate 111. Those skilled in the art will readily understand that the substrates 101 and 111 each may comprise, but are not limited to, one or more of the following: a semiconductor layer, an insulating layer, a conductor layer, and the like.

In some implementations, at the first surface of the first wafer 100, an edge portion of the first metal layer 105 is substantially flush with the first insulating layer. At the first surface of the second wafer 110, an edge portion of the second metal layer 115 is substantially flush with the second insulating layer.

In some implementations, providing the first wafer and the second wafer may comprise: performing a planarization treatment on the wafers. For example, a planarization treatment is performed on the first wafer 100, so that the edge portion of the first metal layer 105 is substantially flush with the first insulating layer 103 at the first surface of the first wafer 100. A planarization treatment is performed on the second wafer 110, so that the edge portion of the second metal layer 115 is substantially flush with the second insulating layer 113 at the first surface of the second wafer 110. Here, those skilled in the art will readily understand that although the purpose of the planarization treatment is to make the metal layer be substantially flush with corresponding insulating layer, as described previously, the planarization treatments (such as, CMP) may result in undesired recesses (or dishing) at the surfaces of the first metal layer 105 and the second metal layer 115.

In FIG. 5A, the first metal layer 105 and the second metal layer 115 are shown to have recesses, respectively. However, it should be understood that the present disclosure is not limited thereto. For example, one or both of the first metal layer 105 and the second metal layer 115 may also have no recess. For such a case, the teaching of the embodiments of the present disclosure may still be applied similarly or adaptively.

In step S403, a pretreatment is performed on one or both of the first wafer and the second wafer. As shown in FIG. 5B, a pretreatment on is performed on one or both of the first wafer 100 and the second wafer 110 to form compound of the metal material at the surface or surfaces of the corresponding one or both of the first metal layer 105 and the second metal layer 115.

In some embodiments, the metal material may comprise copper (Cu); the compound of the metal material may comprise sulfide of copper. For example, the first metal layer 105 and the second metal layer 115 may both be formed of copper. But it should be understood that the present application is not limited thereto.

In some embodiments, the pretreatment may comprise: a sulphidation treatment on the metal material utilizing a sulfur-containing liquid. Specifically, the sulphidation treatment may be performed on the metal material (e.g., copper) of the one or both of the first metal layer 105 and the second metal layer 115 utilizing the sulfur-containing liquid to form sulfide of the metal material 501 at the surface or surfaces of the one or both of the first metal layer 105 and the second metal layer 115.

In some specific implementations, the sulfur-containing liquid may comprise thiourea or thiourea solution (i.e., solution containing thiourea). The sulphidation treatment may be performed at a temperature ranging from 90° C. to 400° C. and for a period ranging from several minutes to several hours. For example, the sulphidation treatment may be performed on one or both of the first metal layer 105 and the second metal layer 115 at 90° C. for several minutes to 1 hour (e.g., 30 minutes) utilizing the thiourea solution. For another example, the sulphidation treatment may be performed, utilizing the thiourea solution, on one or both of the first metal layer 105 and the second metal layer 115 at a temperature of 150° C.-350° C. for several minutes to 30 minutes in a reactor.

Thereafter, in step S405, the first wafer and the second wafer are bonded in a manner that the first metal layer and the second metal layer face each other. As shown in FIG. 5C, the first wafer 100 and the second wafer 110 are bonded in a manner that the first metal layer 105 and the second metal layer 115 face each other.

In step S407, a treatment is performed on the first wafer and second wafer which are bonded. As shown in FIG. 5D, a treatment is performed on the first wafer 100 and second wafer 110 which are bonded, to convert the compound of the metal material into whiskers of the metal material.

In some embodiments, the metal material comprises copper, and the compound of the metal material comprises sulfide of copper. In such a case, the treatment on the first wafer and the second wafer which are bonded may comprise: an annealing treatment on the sulfide of copper in a reducing atmosphere. Thereby, the sulfide of copper can be reduced, and whiskers of copper can be formed at the surface or surfaces of the corresponding one or both of the first metal layer 105 and the second metal layer 115, as shown in FIG. 5D.

The reducing atmosphere may comprise, but is not limited to, hydrogen. The reducing atmosphere may comprise mixed gas of hydrogen and inert gas. In some embodiments, the annealing treatment may be performed at a temperature ranging from 300° C. to 400° C. and for a period ranging from several minutes to several hours. For example, the annealing treatment may be performed at a temperature of 350° C. for a period ranging from several minutes to 1 hour (e.g., 30 minutes) in a reducing atmosphere.

It should be understood that the length of the formed whiskers (and, corresponding process conditions, etc.) may be set according to the size of the recess in the metal layer. For example, in the case of planarization is performed on the metal layer of the wafer with CMP, it is preferred to grow whiskers of a length of about ten nanometers to several hundreds of nanometers.

Alternatively, in some embodiments, a compression treatment may be performed on the first wafer and the second wafer which are bonded at the same time of the annealing treatment.

In the present embodiment, the reduction treatment and the annealing treatment can be combined and performed simultaneously, thereby the process can be simplified and the production efficiency can be enhanced. The annealing treatment is performed on the first wafer 100 and the second wafer 110 which are bonded, thereby the void can be further filled (or eliminated), thereby the interface 505 can be improved, and the bonding strength can be enhanced.

It should be noted that, in the present description, the same reference numerals are used to refer to the same parts or elements, therefore when a part/element has been illustrated or described in a previous drawing or the description, the described or illustrated content may be applied similarly or adaptively to the same part/element that appears later.

Those skilled in the art will readily understand that boundaries between the above described operations or steps are merely illustrative. The multiple operations may be combined into a single operation, a single operation may be distributed in additional operation(s), and operations may be executed at least partially overlapping in time. Moreover, alternative exemplary embodiments may include multiple instances of a particular operation, and the order of operations may be altered in various other exemplary embodiments. However, other modifications, variations and alternatives are also possible. Accordingly, the description and drawings are intended to be illustrative and not for restrictive purpose.

Although some specific exemplary embodiments of the present disclosure have been described in detail with examples, it should be understood by those skilled in the art that the above examples/embodiments are only intended to be illustrative and not to limit the scope of the present disclosure. The exemplary embodiments disclosed herein may be combined arbitrarily without departing from the scope and spirit of the present disclosure. Also, it should be understood by those skilled in the art that various modifications can be made to the exemplary embodiments without departing from the scope and spirit of the present disclosure. The scope of the present disclosure is defined only by the attached claims.

What is claimed is:

1. A wafer bonding method comprising:
providing a first wafer and a second wafer, the first wafer having a first metal layer and a first insulating layer at a first surface thereof, the second wafer having a second metal layer and a second insulating layer at a first surface thereof, the first metal layer and the second metal layer comprising a same metal material;
pretreating one or both of the first wafer and the second wafer, so that whiskers of the metal material are formed at a surface or surfaces of the one or both of the first metal layer and the second metal layer; and
bonding the first metal layer and the second metal layer in a manner that the first metal layer and the second metal layer face each other, to bond the first wafer and the second wafer.

2. The method according to claim 1, wherein
the metal material comprises copper,
the pretreatment comprises:
performing a sulphidation treatment on the one or both of the first metal layer and the second metal layer with a sulfur-containing liquid to form a sulfide of copper at the surfaces or surfaces of the one or both of the first metal layer and the second metal layer; and
performing a reduction treatment on the sulfide of copper in a reducing atmosphere to form copper whiskers at the surface or surfaces of the one or both of the first metal layer and the second metal layer.

3. The method according to claim 1, further comprising:
performing an annealing treatment on the first wafer and the second wafer which are bonded.

4. The method according to claim 1, wherein:
an edge portion of the first metal layer is substantially flush with the first insulating layer at the first surface of the first wafer; and
an edge portion of the second metal layer is substantially flush with the second insulating layer at the first surface of the second wafer.

5. The method according to claim 1, wherein the providing a first wafer and a second wafer comprises:
performing a planarization treatment on the first wafer so that an edge portion of the first metal layer is substantially flush with the first insulating layer at the first surface of the first wafer; and
performing a planarization treatment on the second wafer so that an edge portion of the second metal layer is substantially flush with the second insulating layer at the first surface of the second wafer.

6. The method according to claim 5, wherein the planarization treatment comprises chemical mechanical polishing (CMP).

7. The method according to claim 2, wherein:
the sulfur-containing liquid comprises thiourea or thiourea solution,
the sulphidation treatment is performed at a temperature ranging from 90° C. to 400° C. and for a period ranging from several minutes to several hours.

8. The method according to claim 2, wherein:
the reducing atmosphere comprises hydrogen,
the reduction treatment is performed at a temperature ranging from 150° C. to 400° C. and for a period ranging from several minutes to several hours.

9. The method according to claim 1, wherein bonding the first metal layer and the second metal layer in a manner that that the first metal layer and the second metal layer face each other to bond the first wafer and the second wafer comprises:
bonding the first metal layer and the second metal layer with thermo-compression bonding to bond the first wafer and the second wafer.

10. The method according to claim 3, wherein the annealing treatment is performed at a temperature ranging from 300° C. to 400° C. and for a period ranging from several minutes to several hours.

11. The method according to claim 1, after the pretreating and before bonding the first metal layer and the second metal layer, further comprising:
forming nanoparticles of the metal material on the surface or surfaces of the one or both of the first metal layer and the second metal layer, on which the whiskers of the metal material are formed, with electrochemical deposition.

12. The method according to claim 1, after the pretreating and before bonding the first metal layer and the second metal layer, further comprising:
performing a shaping treatment on the whiskers.

13. The method according to claim 1, after the pretreating and before bonding the first metal layer and the second metal layer, further comprising:
performing a shaping treatment on the whiskers; and
forming, after the shaping treatment, whiskers of the metal material again on the surface or surfaces of the one or both of the first metal layer and the second metal layer on which the whiskers of the metal material are formed.

14. A wafer bonding method comprising:
providing a first wafer and a second wafer, the first wafer having a first metal layer and a first insulating layer at a first surface thereof, the second wafer having a second metal layer and a second insulating layer at a first surface thereof, and the first metal layer and the second metal layer comprising a same metal material;
performing a pretreatment on one or both of the first wafer and the second wafer to form a compound of the metal material at a surface or surfaces of the one or both of the first metal layer and the second metal layer;
bonding the first wafer and the second wafer in a manner that the first metal layer and the second metal layer face each other; and
performing a treatment on the first wafer and the second wafer which are bonded, to convert the compound of the metal material into whiskers of the metal material.

15. The method according to claim 14, wherein
the metal material comprises copper,
the compound of the metal material comprises sulfide of copper, and
the pretreatment comprises:
performing a sulphidation treatment on the one or both of the first metal layer and the second metal layer with a sulfur-containing liquid to form sulfide of copper at the surface or surfaces of the one or both of the first metal layer and the second metal layer.

16. The method according to claim 14, wherein:
the metal material comprises copper,
the compound of the metal material comprises sulfide of copper, and
performing the treatment on the first wafer and the second wafer bonded comprises:
performing an annealing treatment on the sulfide of copper in a reducing atmosphere to form copper whiskers at the surface or surfaces of the one or both of the first metal layer and the second metal layer.

17. The method according to claim 14, wherein:
at the first surface of the first wafer, an edge portion of the first metal layer is substantially flush with the first insulating layer; and
at the first surface of the second wafer, an edge portion of the second metal layer is substantially flush with the second insulating layer.

18. The method according to claim 14, wherein providing the first wafer and the second wafer comprises:
performing a planarization treatment on the first wafer, so that an edge portion of the first metal layer is substantially flush with the first insulating layer at the first surface of the first wafer; and
performing a planarization treatment on the second wafer, so that an edge portion of the second metal layer is substantially flush with the second insulating layer at the first surface of the second wafer.

19. The method according to claim 15, wherein:
the sulfur-containing liquid comprises thiourea or thiourea solution, and
the sulphidation treatment is performed at a temperature ranging from 90° C. to 400° C. and for a period ranging from several minutes to several hours.

20. The method according to claim 16, wherein:
the annealing treatment is performed at a temperature ranging from 300° C. to 400° C. and for a period ranging from several minutes to several hours.
